(19) United States
(12) Patent Application Publication
(10) Pub. No.: US 2023/0420575 A1
(43) Pub. Date: Dec. 28, 2023

(54) METHODS OF FORMING UNIFORMLY DOPED DEEP IMPLANTED REGIONS IN SILICON CARBIDE AND SILICON CARBIDE LAYERS INCLUDING UNIFORMLY DOPED IMPLANTED REGIONS

(71) Applicant: Wolfspeed, Inc., Durham, NC (US)

(72) Inventors: Rahul R. Potera, Apex, NC (US); Steven Rogers, Cary, NC (US); Edward Robert Van Brunt, Cary, NC (US)

(21) Appl. No.: 17/849,037

(22) Filed: Jun. 24, 2022

(51) Int. Cl. H01L 29/808; H01L 29/16; H01L 29/10; H01L 21/04; H01L 29/66

(52) U.S. Cl. CPC H01L 29/8083; H01L 29/1608; H01L 29/1058; H01L 21/046; H01L 29/66068

(57) ABSTRACT

A method of forming a buried implanted region in a silicon carbide semiconductor layer includes implanting first dopant ions into the silicon carbide semiconductor layer at a first dose and first implant energy to form a first channelized doping profile having a first de-channeled peak at a first depth in the silicon carbide semiconductor layer and a first channeled peak at a second depth that is greater than the first depth. Second dopant ions are implanted into the silicon carbide semiconductor layer at a second dose and second implant energy to form a second channelized doping profile. The second channelized doping profile has a second channeled peak at a third depth in the silicon carbide semiconductor layer that is between the first depth and the second depth. The first channelized doping profile and the second channelized doping profile form a combined doping profile that defines the buried implanted region.

### FIELD

The present disclosure relates to semiconductor devices. In particular, the disclosure relates to silicon carbide semiconductor devices having implanted regions.

### BACKGROUND

Power electronic devices manufactured using silicon carbide (SiC) are capable of high blocking voltages. For power devices having blocking voltages in the 600V-1000V range, SiC junction field effect transistors (JFETs) have two to three times smaller chip area than SiC metal-oxide semiconductor field effect transistors (MOSFETs). SiC JFETs can also be manufactured with a simpler manufacturing process than MOSFETs, which can lead to lower manufacturing costs. Moreover, SiC JFET devices have no SiO₂—SiC interface, which may increase device reliability, as oxide layers may break down under high voltage operation. JFET devices have the drawback of being normally-on devices. However, their advantages may outweigh their disadvantages in power applications, such as high reliability Si—SiC heterogeneously integrated circuits.

### SUMMARY

A method of forming a buried implanted region in a silicon carbide semiconductor layer according to some embodiments includes implanting first dopant ions having a first conductivity type into the silicon carbide semiconductor layer along a first axis at a first dose and first implant energy to form a first channelized doping profile. The first channelized doping profile has a first de-channeled peak at a first depth in the silicon carbide semiconductor layer and a first channeled peak at a second depth in the silicon carbide semiconductor layer that is greater than the first depth. The method further includes implanting second dopant ions having the first conductivity type into the silicon carbide semiconductor layer along the first axis at a second dose and second implant energy to form a second channelized doping profile. The second channelized doping profile has a second channeled peak at a third depth in the silicon carbide semiconductor layer that is between the first depth and the second depth. The first channelized doping profile and the second channelized doping profile form a combined doping profile that defines the buried implanted region.

The method may further include annealing the silicon carbide semiconductor layer after implanting the first and/or second dopant ions to activate the first and second dopant ions.

The first dose may be selected to form the de-channeled peak in the silicon carbide semiconductor layer at the first depth when implanted at the first implant energy.

Implanting the first dopant ions and/or implanting the second dopant ions may be performed at room temperature. In some embodiments, implanting the first dopant ions and/or implanting the second dopant ions is performed at a temperature that is lower than room temperature.

In some embodiments, the combined doping profile has a variation in doping concentration between the de-channeled peak and the channeled peak of less than about 15%. In some embodiments, the combined doping profile has a variation in doping concentration between the de-channeled peak and the channeled peak between about 5% and about 10%, and in some embodiments, the combined doping profile has a variation in doping concentration between the de-channeled peak and the channeled peak of about 5%.

The buried implanted region may be a channel region of a vertical semiconductor device, such as a vertical junction field effect transistor device, or a current spreading layer of a semiconductor device.

The buried implanted region may have a dopant concentration tail beneath the buried implanted region that decreases at a rate of greater than about 1.0 E17 atoms/(cm³-micron), and in some embodiments greater than about 1.2 E17 atoms/(cm³-micron).

The first depth may be less than about 1.5 microns and the second depth may be greater than about 2 microns. A distance between the first depth and the second depth may be greater than about 1 micron.

The first implant dose and the second implant dose may each be less than about 1E13/cm². In some embodiments, the first implant energy is greater than the second implant energy.

A silicon carbide semiconductor layer according to some embodiments includes a buried implanted region that is buried in the silicon carbide layer at a first depth from a surface of the silicon carbide layer, the buried implanted region defined by an implant doping profile having a first thickness between the first depth and a second depth, wherein the second depth is greater than the first depth. The buried implanted region may have a variation in doping concentration between the de-channeled peak and the channeled peak of less than about 15%.

A silicon carbide semiconductor layer according to some embodiments includes a buried implanted region that is buried in the silicon carbide layer at a first depth from a surface of the silicon carbide layer, the buried implanted region defined by an implant doping profile having a first thickness between the first depth and a second depth, wherein the second depth is greater than the first depth. The buried implanted region has a dopant concentration tail beneath the buried implanted region that decreases at a rate of greater than about 1.0E17 atoms/(cm³-micron).

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 illustrates a vertical JFET device structure.

FIG. 2 is a schematic diagram illustrating the relative locations of various crystallographic axes in 4H silicon carbide.

FIGS. 3A-3C illustrate the lattice structure of 4H silicon carbide as viewed along the <0001>, <11-23> and <11-20> crystallographic axes, respectively.

FIG. 4 is a graph of secondary ion mass spectroscopy (SIMS) data illustrating implanted dopant concentrations for phosphorus ions implanted at various doses into 4H silicon carbide along the <0001> crystallographic axis at an implantation energy of 1.5 MeV.

FIGS. 5A and 5B illustrate schematic examples of channeled implant profiles in silicon carbide.

FIG. 6 illustrates SIMS data showing example doping profiles formed in a silicon carbide semiconductor layer including a combined doping profile for a JFET structure according to some embodiments.

FIG. 7 illustrates a method of forming a buried implanted region in a silicon carbide semiconductor layer according to some embodiments.

FIG. 8 illustrates implantation of ions along the <0001> crystallographic axis of a silicon carbide layer.

FIG. 9 illustrates an example circuit that includes a JFET device according to some embodiments.

### DETAILED DESCRIPTION OF THE DISCLOSURE

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices, such as MOSFETs, insulated gate bipolar transistors (IGBTs) and other types of devices.

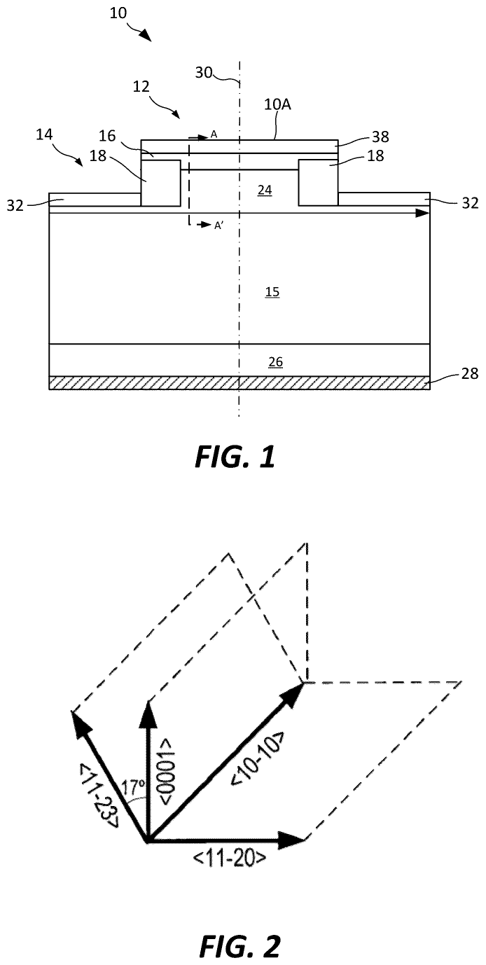

An n-channel vertical JFET structure 10 is shown in FIG. 1. The vertical JFET structure includes an n+ drain layer 26 on which an n− drift layer 15 is formed. An n-type channel region 24 is on the drift layer 15, and an n+ source layer 16 is on the channel region 24. An n++ source contact layer 38 is on the n+ source layer 16. The channel region 24, source layer 16 and source contact layer 38 are provided as part of a mesa 12 above the drift layer 15. Trenches 14 are formed in the structure 10 adjacent the mesa 12.

A p+ gate region 18 is provided as part of the mesa 12 adjacent the channel region 24. A p++ gate contact region 32 is provided adjacent the gate region 18.

The vertical JFET unit cell structure 10 is symmetrical about the axis 30 and includes two gate regions 18 as part of the mesa 12 on opposite sides of the channel region 24.

The channel of the vertical JFET structure 10 is formed within the mesa 12. The channel width is into the plane of FIG. 1, and the channel length is in the vertical direction. Such a vertical JFET structure with a short channel length may also be called a static-induction transistor (SIT). In a SIT, the channel length is chosen based on a trade-off between low on-resistance in the on-state (short channel) and resistance to drain-induced barrier lowering (DIBL) in the off-state. A p-channel JFET may have a similar structure, but the conductivity types are reversed from those shown in FIG. 1.

In operation, conductivity between the source layer 16 and the drain layer 26 is modulated by applying a reverse bias to the gate region 18 relative to the source layer 16. To switch off an n-channel device such as the JFET structure 10, a negative gate-to-source voltage, or simply gate voltage (V_{GS}) is applied to the gate region 18. When no voltage is applied to the gate region 18, charge carriers can flow freely from the source layer 16 through the channel region 24 and the drift layer 15 to the drain layer 26.

In a JFET device such as the JFET device 10 shown in FIG. 1, the conductivity of the channel between the source region 16 and the drift layer 15 is controlled by an electric field in a direction transverse to the source-drain axis 30. The electric field is controlled by a reverse bias voltage applied between the gate and source terminals. Different gate voltages can thus switch the JFET between OFF and ON states. Threshold voltage is that gate voltage at which the channel begins to conduct, and is an important property of the device. Overdrive of on-state gate voltage above the threshold voltage provides low resistance in the on-state and a margin of off-state gate voltage below threshold voltage keeps the channel off in the off-state even at high drain bias voltages.

Dopant concentration in the channel is an important parameter of a JFET device, as it affects the relationship between gate bias and threshold voltage. A substantially constant, predictable channel doping is thus preferable to have low on-resistance and low off-state leakage.

In a vertical SiC n-channel JFET structure 10 as shown in FIG. 1, the source region consists of an n++ contact region 38 and an n+ transition region 16, which may be about 1 micron deep.

The JFET channel region 24 is adjacent the gate region 18 between the n+ transition region 16 and the drift layer 15. To behave as a long-channel MOSFET without drain-induced barrier lowering (DIBL), the JFET channel 24 typically is 1-2 um long, which for a vertical channel device would be 1-2 um deep in the structure. Thus, the channel region extends from a depth of about 1 micron below the top surface 10A of the structure to a depth of 2.5 to 3 microns below the surface 10A. The JFET channel 24 can be doped epitaxially. However, doping variation in SiC epitaxy can be up to 20%, which would introduce a 20% variation in channel doping (Nch) in equation [1] below for threshold voltage (V_{T}).

The threshold voltage V_{T} of a vertical SiC JFET device is given by equation [1], in which V_{bi} is the built-in voltage of the P-N junction between the gate region 18 and the channel region 24, N_{ch} is the doping concentration of the channel region 24, q is the charge of an electron, V_{barrier} is the potential barrier in the channel at which V_{T} is defined, W is the half-channel depth (i.e., the depth of the channel to from the gate region 18 to the centerline 30 of the structure), and £ is the permittivity of silicon carbide.

Equation [2] relates the change in threshold voltage (dV_{T}) to change in channel doping (dN_{ch}).

$${V}_{T} = {V}_{bi} - \frac{{qN}_{ch} {W}^{2}}{2 ϵ} - {V}_{barrier} \qquad [ 1 ]$$

$$\frac{{dV}_{T}}{{dN}_{Ch}} = - \frac{{qW}^{2}}{2 ϵ} \qquad [ 2 ]$$

With typical values of N_{ch=}5E16/cm3, half-channel depth (W)=0.33 microns, electron charge (q), V_{bi} in SiC of about 3V, and the potential barrier in the channel at which V_{T} is defined (Vbarrier) of about −2V, the threshold voltage V_{T} is centered at −3.95V. With a 20% variation of N_{ch}, V_{T} varies between −5.45V and −4.46V, which is a spread of about 1V. Such a variation might be acceptable in some applications but not in others. In addition to N_{ch}, V_{T} also varies with channel depth W, which for a trench JFET is very sensitive to the width of the mesa. In order to reduce this sensitivity, there is a floor on how low W can be reduced while also not increasing on-state resistance significantly. However, equation [2] shows that sensitivity of V_{T} to N_{ch} is proportional to W², which means that sensitivity cannot be reduced without impacting on-state resistance negatively. As a corollary, equation [2] also shows that if variation in N ch can be reduced, then W can be increased while keeping the same variation in V_{T}. In addition to variation of V_{T} with N_{ch}, a typical 0.2 um variation in mesa width due to process imprecision leads to a 0.2 micron variation in W, which with the same typical values as cited above can lead to approximately a 3V variation in V_{T} between −6.56V and −3.56V. Thus, more precise control of N_{ch} can remove one important factor in variation of V_{T} in a JFET.

A JFET channel is typically formed either using epitaxy or random implants. Doping during epitaxial growth may suffer from inherent variability (e.g., 20% typically in SiC). Random (non-channeled) implantation of dopant ions in silicon carbide may be limited to depths of up to about 0.5 to 1 micron without using impractically high implant energies, which can have very low beam current and hence little throughput. Moreover, the use of high implant energies can cause significant undesirable lattice damage to the silicon carbide layer, which must be annealed at high temperatures to repair. Channel regions for vertical channel JFETs may need to be about 1 to 3 microns deep, and should preferably be doped uniformly and with little variation. It may be difficult to satisfy these requirements using epitaxial doping or random implants.

Some embodiments described herein utilize channeled implants to form a buried region in a silicon carbide layer, such as a channel region of a vertical JFET device. In particular embodiments, ions may be implanted substantially parallel to a <0001>, <11-20> or <11-23> axis of a silicon carbide layer to obtain channeled implants. Multiple channeled implants may be performed to obtain a doped buried layer that has a substantially uniform doping profile as a function of depth within the silicon carbide layer. For example, in some embodiments, multiple successive implantations may be performed at different energies and/or doses form a substantially uniformly doped JFET channel region 24 between depth of 1 micron and 2.5-3 microns below the surface 10A. The implantations may be performed at a maximum implantation energy of 1.8 MeV and a total dopant ion dose that stays below an upper limit above which significant de-channeling of the dopant concentration/range starts.

Channeling of implants may occur when ions are implanted parallel or nearly parallel to a crystal axis of a semiconductor layer so that there is a lower likelihood of the implanted ion colliding with the crystal lattice of the semiconductor layer the surface of the semiconductor layer compared to implantation at a random angle relative to the crystal lattice. Channeled implants may therefore penetrate much deeper into the semiconductor layer than random implants.

FIG. 2 is a schematic diagram illustrating the relative orientations of various crystallographic axes in 4H silicon carbide. As shown in FIG. 2, the <10-10> crystallographic axis is perpendicular to each of the <0001>, <11-20> and <11-23> crystallographic axes. The <11-20> crystallographic axis is perpendicular to the <0001> crystallographic axis, and the <11-23> crystallographic axis is offset by about 17° from the <0001> crystallographic axis in the direction away from the <11-20> crystallographic axis.

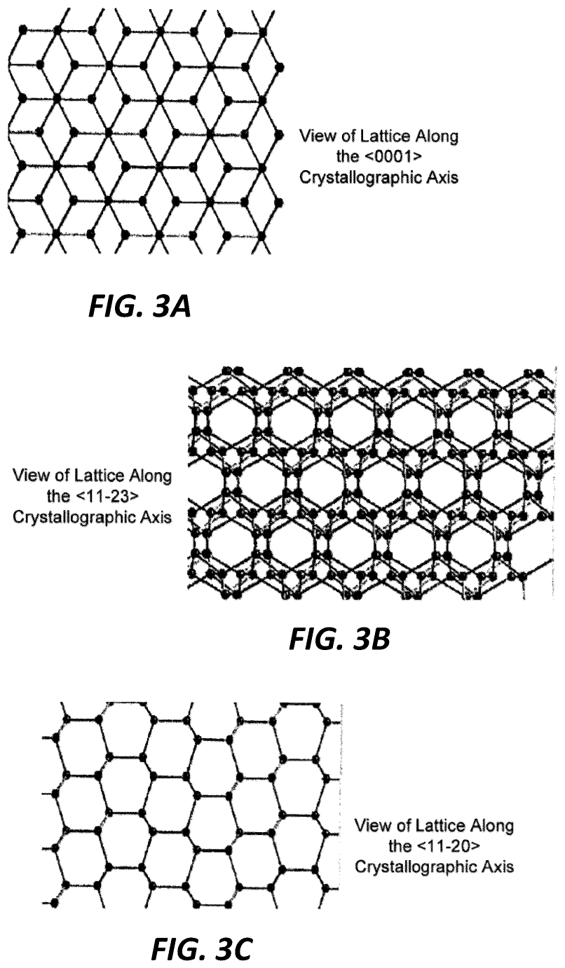

FIGS. 3A-3C illustrate the lattice structure of 4H silicon carbide as seen along the <0001>, <11-23> and <11-20> crystallographic axes, respectively. As shown in FIG. 3A, the density of atoms at the surface (the atoms are shown by the small circles in FIG. 3A) is relatively low, which is a favorable condition for deeper ion implant depths. A plurality of channels are provided between the atoms which allow for channeling of the implanted ions to relatively deeper depths into the semiconductor material. However, the channels themselves are relatively small in cross-sectional area. Relatively speaking, the smaller a channel is in cross-sectional area, the shallower the implant depth. Thus, while ion implantation along the <0001> crystallographic axis will exhibit channeling, the implant depths achievable are still limited.

FIG. 3B illustrates the lattice structure of 4H silicon carbide as viewed along the <11-23> crystallographic axis. The lattice structure will look the same as shown in FIG. 3B when viewed along any of the <−1-123>, <1-213>, <−12-13>, <2-1-13> and <−2113> crystallographic axes. Given the hexagonal lattice of 4H silicon carbide, the six crystallographic axes listed above are all offset by 17 degrees from the <0001> crystallographic axis and are spaced apart from each other by 60 degree increments. The vectors that are offset by 17 degrees from the <0001> crystallographic axis form a cone that rotates through 360 degrees. The <11-23>, <−1-123>, <1-213>, <−12-13>, <2-1-13> and <−2113> crystallographic axes all extend along this cone, and are separated from each other by 60 degrees. At most rotation angles about this cone, the lattice structure will appear “crowded” with closely-spaced atoms throughout. However, as shown with reference to FIG. 3B, at six different locations that correspond to the <11-23>, <−1-123>, <1-213>, <−12-13>, <2-1-13> and <−2113> crystallographic axes, the atoms “line up” so that distinct channels appear in the lattice structure. As can be seen in FIG. 3B, along these six crystallographic axes, the density of atoms at the surface is increased as compared to the example of FIG. 3A, which will typically result in increased scattering of ions. Advantageously, however, the channels that are provided between the atoms have a larger cross-sectional area as compared to the channels in the example of FIG. 3A. As will be shown herein, this may allow for increased implant depths.

As can be seen in FIG. 3C, when 4H silicon carbide is viewed along the <11-20> crystallographic axis, the density of atoms at the surface may be very low, and channels having large cross-sectional areas are provided within the lattice structure. Such a structure may allow for very deep implant depths. Unfortunately, however, the <11-20> crystallographic axis is typically nearly perpendicular to the major faces of a silicon carbide wafer when the wafer is cut in a traditional manner, and hence it may be difficult to provide silicon carbide wafers that have a major face cut along, or at a relatively small tilt from, the <11-20> crystallographic axis. Thus, ion implantation along the <11-20> crystallographic axis may not be an option in many applications.

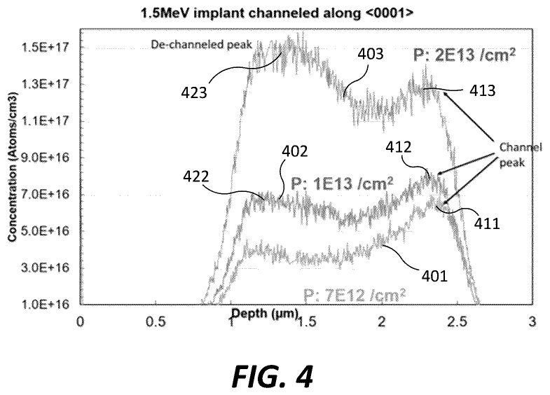

When ions are implanted along the <0001> axis of a hexagonal silicon carbide polytype (such as 2H, 4H or 6H), the resulting doping profile may exhibit a so-called “de-channeled” peak near the surface of the silicon carbide layer depending on the dose of the implant. A de-channeled peak refers to a peak in the implanted doping concentration that is formed as a result of implanted ions colliding with the crystal lattice of the silicon carbide layer near the surface of the layer rather than channeling deeply in to the semiconductor layer. When the implant dose is increased, the likelihood of de-channeling of ions occurring increases. For example, FIG. 4 is a graph of secondary ion mass spectroscopy (SIMS) data illustrating implanted dopant concentrations for phosphorus (P) ions implanted at various doses into 4H silicon carbide along the <0001> crystallographic axis at an implantation energy of 1.5 MeV.

In particular, FIG. 4 illustrates three different doping profiles formed by implantation of phosphorus ions into a hexagonal (4H) silicon carbide layer along the <0001> crystallographic axis. Each of the implantations was performed at an implant energy of 1.5 MeV. Doping profile 401 corresponds to a dose of 7E12/cm2, doping profile 402 corresponds to a dose of 1E13/cm2, and doping profile 403 corresponds to a dose of 2E13/cm2. As

As can be seen in FIG. 4, the doping profile 403 (formed with the highest dose) exhibits a significant de-channeled peak 423 at a depth of about 1 micron from the surface of the silicon carbide layer and a channeled peak 413 at a depth of about 2.25 microns from the surface of the silicon carbide layer. In fact, the de-channeled peak has a higher doping concentration at about 1.5E17/cm3 than the channeled peak 413 at about 1.3 E17/cm3.

As seen in the doping profile 402, at an implant dose of 1E13/cm2, a de-channeled peak 422 is just beginning to form in the doping profile. However, it is slightly lower than the channeled peak 412. Similarly, in the doping profile 401, the de-channeled peak 422 is even less pronounced compared to the channeled peak 411.

With 1.5 MeV implants channeled along the <0001> crystallographic axis as shown in FIG. 4, when the implant dose is significantly more than 1E13/cm2, there is a substantial amount of de-channeling in the implant. However, at a dose of about 1E13/cm2, the channeled and de-channeled implant peaks are nearly the same.

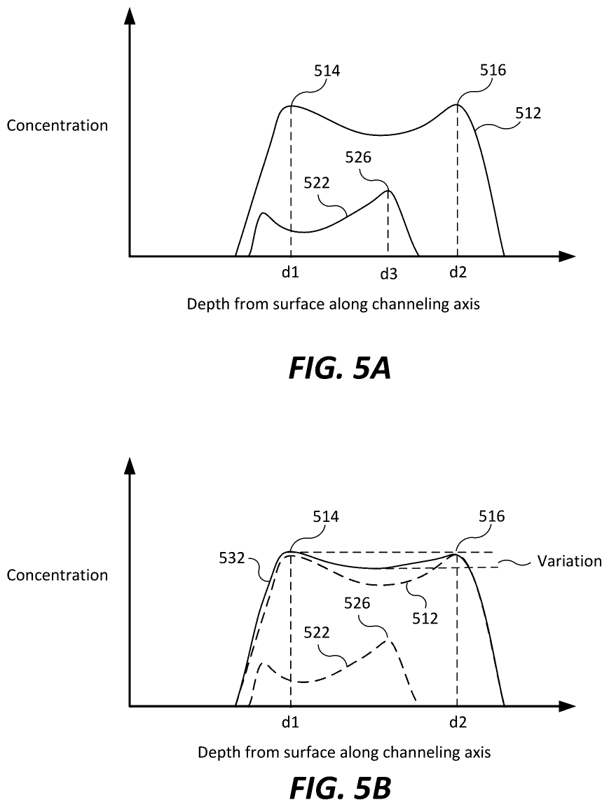

Some embodiments described herein use the presence of a de-channeled peak in a channeled implant profile to help form a highly uniform buried implanted region in a silicon carbide layer by combining multiple successive implants to form a combined implant profile. FIGS. 5A and 5B illustrate schematic examples of channeled implant profiles in silicon carbide. Referring to FIG. 5A, a first doping profile 512 is formed by a first implantation into a silicon carbide layer and a second doping profile 522 is formed by a second implantation into the semiconductor layer. The first implantation is performed at a high enough dose to form a de-channeled peak 514 at a first depth d1 a high enough energy to form a first channeled implant peak 516 at a second depth d2 that is deeper than the first depth d1. The first channeled implant peak 516 and the de-channeled implant peak 514 have about the same dopant concentration. In some cases, there may be less than a 15% difference between the doping concentration at the de-channeled peak 514 and the doping concentration at the first channeled peak 516. In some cases, the difference between doping concentrations at the de-channeled peak 514 and the first channeled peak 516 may be from about 5% to about 10%, and in some cases the difference between doping concentrations at the de-channeled peak 514 and the first channeled peak 516 may be about 5% or less.

The second implantation is performed at a high enough energy to form a second channeled implant peak 526 at a depth d3 that is between d1 and d2, but at a low enough dose so as not to form a significant de-channeled peak. To place the second channeled peak shallower than the first channeled peak, the second implantation may be performed at a lower implant energy than the first implant. That is, the second channeled implant can be used to fill in the valley between the channeled and de-channeled peaks 514, 516 to form a substantially uniform doping profile.

The first depth d1 may be less than about 1.5 microns, and the second depth d2 may be greater than about 2 microns. The distance from d1 to d2 may be greater than about 1 micron.

Some embodiments use chained (i.e., sequential) channeled implants with a maximum energy of 1.8 MeV to 2 MeV and a combined dose no more than about 1.5E13/cm² to form a buried region in a silicon carbide layer that has less than about 5% variation in doping concentration along the channel length and less than about 5% variation in doping concentration between structures across a wafer (e.g., across a 200 mm SiC wafer). For a JFET structure, the buried region may be a channel region or channel layer. The balance achieved between the channeled and de-channeled peaks of the implants may enable substantially uniform doping along the length of the vertical channel of the JFET (i.e., depth into the mesa), as well as in multiple devices across a wafer.

FIG. 5B illustrates a combined doping profile 532 that is the combination of the first doping profile 512 and the second doping profile 522. As seen in FIG. 5B, because the channeled peak 526 of the second doping profile 522 is between the de-channeled peak 514 and the channeled peak 516 of the first doping profile 512, the combined doping profile has a highly uniform concentration between the depths d1 and d2 in the silicon carbide semiconductor layer.

In some embodiments, by appropriately selecting the implant conditions of the first and second implantations, a buried doped region, defined as the region between the de-channeled peak 514 and the first channeled peak 516, may be formed in a semiconductor having a variation of doping concentration of less than about 15%. In some embodiments, the variation of doping concentration in the buried doped region may be from about 5% to about 10%, and in some embodiments, the variation of doping concentration in the buried doped region may be about 5%.

Moreover, because of the nature of channeled implants, the doping concentration of the buried doped region may have a very sharp gradient, or drop-off, at the bottom of the region. For example, in some embodiments, the buried implanted region has a dopant concentration tail beneath the buried implanted region that decreases at a rate of greater than about 1.0E17 atoms/(cm³-micron), in some embodiments at a rate of greater than about 1.2E17 atoms/(cm³-micron). In some embodiments, the buried implanted region has a dopant concentration tail beneath the buried implanted region that decreases at a rate of greater than about 1.0E17 atoms/(cm³-micron) and less than 1.5E17 atoms/(cm³-micron).

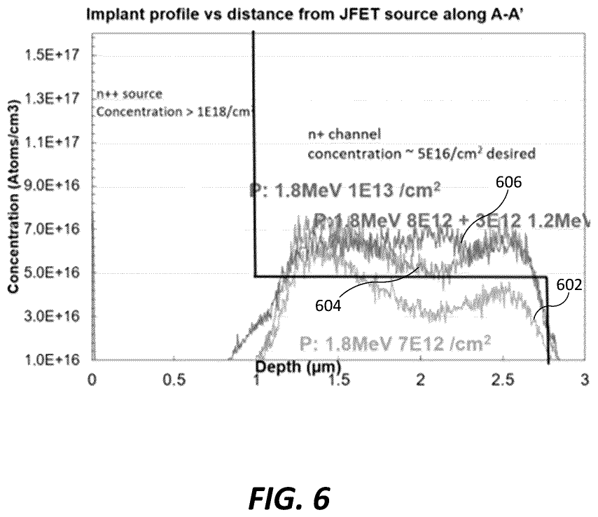

FIG. 6 illustrates SIMS data showing example doping profiles formed in a silicon carbide semiconductor layer including a combined doping profile for a JFET structure 10 according to some embodiments. In particular, for an n-channel SiC JFET structure, it is desirable to form a buried channel region having a uniform doping concentration of between about 5E16 and about 7E16. The doping profiles of FIG. 6 are taken from a vertical cross section of a JFET structure 10 along line A-A′ of FIG. 1.

FIG. 6 illustrates a first doping profile 602 formed by a single implantation of phosphorus into 4H—SiC at an implant energy of 1.8 MeV and a dose of 7E12/cm² along the <0001> axis. The first doping profile 602 has a de-channeled peak of about 1E16/cm³ at about 1.25 microns, but exhibits variation over the depth of the implant from about 1.25 microns to about 2.7 microns. A second doping profile 604 is formed by a single implantation at an implant energy of 1.8 MeV and a dose of 1E13/cm². The second doping profile 604 has a de-channeled peak of about 7E16/cm3 at about 1.25 microns, but also exhibits variation over the depth of the region.

A third doping profile 606 is formed by a first implantation at an energy of 1.8 MeV and a dose of 8E12/cm2 and a second implantation at an energy of 1.2 MeV and a dose of 3E12/cm². The third doping profile is highly uniform at about 6 E16/cm³ to 7E16/cm³ over the depth of the implanted region from about 1.25 microns to about 2.7 microns.

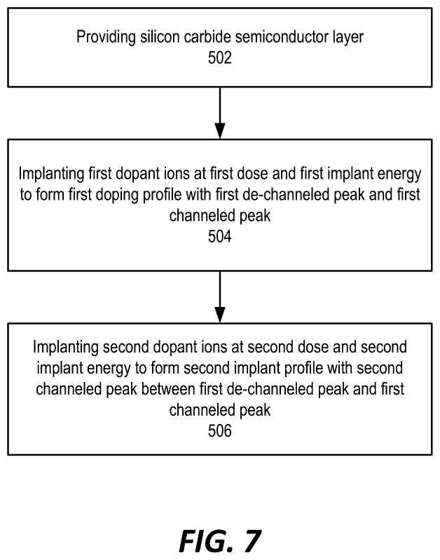

Referring to FIG. 7, a method of forming a buried implanted region in a silicon carbide semiconductor layer are illustrated. The method includes providing a silicon carbide layer (block 502). First dopant ions having a first conductivity type are implanted into the silicon carbide semiconductor layer along a first axis at a first dose and first implant energy to form a first channelized doping profile (block 504). The first channelized doping profile has a first de-channeled peak at a first depth in the silicon carbide semiconductor layer and a first channeled peak at a second depth in the silicon carbide semiconductor layer that is greater than the first depth. The first axis may be parallel to a <0001>, <112-3> or <11-20> crystallographic axis of the silicon carbide semiconductor layer.

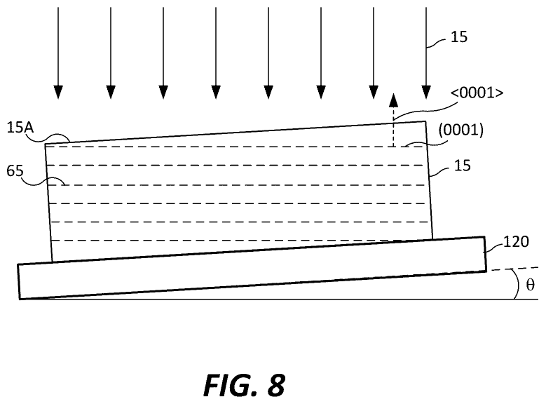

Brief reference is made to FIG. 8, which illustrates implantation of ions along the <0001> crystallographic axis of an off-axis silicon carbide layer 15. The silicon carbide layer 15 may include a substrate (not shown) on which the layer is formed. The silicon carbide layer 15 is mounted onto a stage 120 for the implantation. The silicon carbide layer may be formed at an off-axis angle of, for example, 4°, relative to a crystallographic plane of the layer, such as the (0001) plane. In particular, the silicon carbide layer 15 may be grown as an epitaxial layer on a silicon carbide substrate that was sliced at an off-axis angle when it was fabricated.

Thus, the epitaxial layers 65 of the silicon carbide layer 15 may not be parallel to the top surface 15A of the silicon carbide layer, but rather may be tilted at an angle corresponding to the off-axis angle at which the silicon carbide layer was formed.

To perform channeled ion implantation, the stage 120 may be tilted by an angle θ that is equal to the off-axis angle so that the ions 125 are implanted parallel to the <0001> crystallographic axis of the silicon carbide layer 15.

Referring again to FIG. 7, the method further includes implanting second dopant ions having the first conductivity type into the silicon carbide semiconductor layer along the first axis at a second dose and second implant energy to form a second channelized doping profile. The second channelized doping profile may have a second channeled peak at a third depth in the silicon carbide semiconductor layer that may be between the first depth and the second depth. The first channelized doping profile and the second channelized doping profile form a combined doping profile that defines the buried implanted region.

The buried implanted region may have a dopant concentration tail beneath the buried implanted region that decreases at a rate of greater than about 1.0E17 atoms/(cm³-micron), and in some embodiments at a rate of greater than about 1.2E17 atoms/(cm³-micron). In some embodiments, the buried implanted region has a dopant concentration tail beneath the buried implanted region that decreases at a rate of greater than about 1.0E17 atoms/(cm³-micron) and less than 1.5E17 atoms/(cm³-micron).

The first depth may be less than about 1.5 microns and the second depth may be greater than about 2 microns. The distance between the first depth and the second depth may be greater than about 1 micron.

The first implant dose and the second implant dose may each be less than about 1E13/cm², and may have a combined dose of about 1.5E13/cm² or less.

The first implant energy may be greater than the second implant energy.

The method may further include annealing the silicon carbide semiconductor layer after implanting the first and second dopant ions to activate the first and second dopant ions.

In some embodiments, the first dose may be selected to form the de-channeled peak in the silicon carbide semiconductor layer at the first depth when implanted at the first implant energy.

In some embodiments, implanting the first dopant ions and/or implanting the second dopant ions may be performed at room temperature or at a temperature that may be lower than room temperature.

The combined doping profile may have a variation in doping concentration between the de-channeled peak and the channeled peak of less than about 15%.

In some embodiments, the combined doping profile may have a variation in doping concentration between the de-channeled peak and the channeled peak between about 5% and about 10%, and in some embodiments, the combined doping profile may have a variation in doping concentration between the de-channeled peak and the channeled peak of about 5%.

The buried implanted region may be a channel region of a vertical semiconductor device, such as a vertical junction field effect transistor device. In some embodiments, the buried implanted region may be a current spreading layer of a semiconductor device.

Some embodiments provide a silicon carbide semiconductor layer having a buried implanted region that is buried in the silicon carbide layer at a first depth from a surface of the silicon carbide layer. The buried implanted region is defined by an implant doping profile having a first thickness between the first depth and a second depth, wherein the second depth is greater than the first depth. The buried implanted region has a variation in doping concentration between the de-channeled peak and the channeled peak of less than about 15%.

As noted above, a JFET channel is typically formed either using epitaxy or random implants. However, it may be difficult to achieve the required depth and/or thickness of a buried region or the required doping uniformity using either epitaxial doping or random implantation.

As discussed above, using chained channeled implants into SiC at room or lower temperatures, deep and uniformly doped regions can be obtained. An advantage of using chained channeled implants to form the channel of the vertical JFET is that the channel region can have a substantially uniform dopant concentration both along the channel length of an individual JFET cell, and between JFET cells and JFET devices across a large wafer area. Additionally, channeled implants may have a more abrupt implant tail, which allows the implant to be confined better in the desired JFET channel, in contrast to random implants in SiC which have deep tails that encroach into the drift region of the device and may worsen the trade-off between device parameters.

Some advantages of this invention maybe quantified by considering three scenarios, namely, (1) a JFET channel doped at 5E16/cm³ that is 1.7 microns long, grown epitaxially with a 20% variation (+1-10%), (2) a JFET channel doped at 5E16/cm³ and only 0.5 microns deep, formed with random implants (channel length is limited because implant energy is limited to 1.8 keV, which gives an implant up to 1.5 microns deep, and the source region consumes 1 micron, leaving 0.5 microns length of channel), and (3) a JFET channel 5E16 doped, 1.7 microns long, formed using 1.8 MeV+1.2 MeV chained channeled implants that extend 2.7 microns deep along the <0001> direction, which gives an implanted region up to 2.7 microns deep. The source region consumes 1 micron, leaving 1.7 microns of channel length.

With a process variation of 0.2 microns in mesa width, the results are tabulated in Table 1.

TABLE 1
Comparison Results of Epitaxial Doping, Random Implants and Channeled Implants

| | Mesa.min | Mesa.max | Nch_min | Nch_max | VTmin | VTmax | | Rsp.max | BV | |
|---|---|---|---|---|---|---|---|---|---|---|
| Epi | 1.1 um | 1.3 um | 1.35E16/cm³ | 1.65E16/cm³ | −2.2 V | −1.0 | V | 83 mΩmm² | 850 | V |
| Random | 1.1 um | 1.3 um | 1.5E16/cm³ | 1.5E16/cm³ | −2.0 V | −1.1 | V | 64 mΩmm² | <400 | V |
| Channeled | 1.1 um | 1.3 um | 1.5E16/cm³ | 1.5E16/cm³ | −2.0 V | −1.17 | V | 80 mΩmm² | 850 | V |

As seen in Table 1, using epitaxially grown channel leads to a delta V_{T} of 1.2V (range between −2.2V and −1V) under the given process variation. The delta V_{T} can be reduced to 0.9V, i.e. a reduction of 25%, by using an implanted channel. However, using random implants, the channel length can only be up to 0.5 microns in length, which is a short-channel device that may experience significant DIBL at high drain voltages. With a 750V rated drift region, such a device can only block <400V, which is not sufficient for a 400V rail application. Using channeled implants, V_{T} variation can be restricted, while also maintaining the channel length required to not experience DIBL.

In addition to the reduction variation in V_{T}, forming an implanted channel region may also reduce the maximum specific on-resistance of the device by up to about 4%.

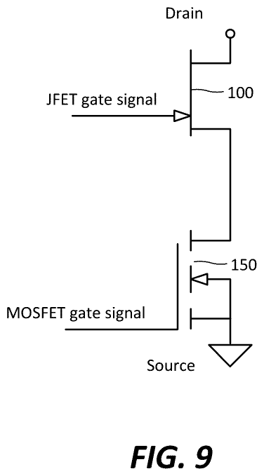

FIG. 9 illustrates an example circuit that includes a JFET device according to some embodiments. As shown in FIG. 9, a vertical SiC JFET 100 according to some embodiments can be connected in a modified cascode topology with a Silicon MOSFET 150, where the SiC JFET gate is direct-driven, and in which it is desirable for the variation of SiC JFET threshold voltage to be very low.

A JFET device as described herein may also be advantageously used for other SiC JFET applications such as in a solid-state circuit breaker as a normally-on SiC JFET switch.

Although embodiments of the inventive concepts have been described in considerable detail with reference to certain configurations thereof, other versions are possible. The field plates and gates can also have many different shapes and can be connected to the source contact in many different ways. Accordingly, the spirit and scope of the invention should not be limited to the specific embodiments described above.

1. A method of forming a buried implanted region in a silicon carbide semiconductor layer, comprising:
implanting first dopant ions having a first conductivity type into the silicon carbide semiconductor layer along a first axis at a first dose and first implant energy to form a first channelized doping profile, wherein the first channelized doping profile has a first de-channeled peak at a first depth in the silicon carbide semiconductor layer and a first channeled peak at a second depth in the silicon carbide semiconductor layer that is greater than the first depth; and
implanting second dopant ions having the first conductivity type into the silicon carbide semiconductor layer along the first axis at a second dose and second implant energy to form a second channelized doping profile, wherein the second channelized doping profile has a second channeled peak at a third depth in the silicon carbide semiconductor layer that is between the first depth and the second depth;
wherein the first channelized doping profile and the second channelized doping profile form a combined doping profile that defines the buried implanted region.

2. The method of claim 1, further comprising:
annealing the silicon carbide semiconductor layer after implanting the first and/or second dopant ions to activate the first and second dopant ions.

3. The method of claim 1, wherein the first dose is selected to form the de-channeled peak in the silicon carbide semiconductor layer at the first depth when implanted at the first implant energy.

4. The method of claim 1, further wherein implanting the first dopant ions and/or implanting the second dopant ions is performed at room temperature.

5. The method of claim 1, wherein implanting the first dopant ions and/or implanting the second dopant ions is performed at a temperature that is lower than room temperature.

6. The method of claim 1, wherein the combined doping profile has a variation in doping concentration between the de-channeled peak and the channeled peak of less than about 15%.

7. The method of claim 6, wherein the combined doping profile has a variation in doping concentration between the de-channeled peak and the channeled peak between about 5% and about 10%.

8. The method of claim 6, wherein the combined doping profile has a variation in doping concentration between the de-channeled peak and the channeled peak of about 5%.

9. The method of claim 1, wherein the buried implanted region comprises a channel region of a vertical semiconductor device.

10. The method of claim 9, wherein the vertical semiconductor device comprises a vertical junction field effect transistor device.

11. The method of claim 1, wherein the buried implanted region comprises a current spreading layer of a semiconductor device.

12. The method of claim 1, wherein the buried implanted region has a dopant concentration tail beneath the buried implanted region that decreases at a rate of greater than about 1.0 E17 atoms/(cm³-micron).

13. The method of claim 12, wherein the dopant concentration tail decreases at a rate of greater than about 1.2 E17 atoms/(cm³-micron).

14. The method of claim 1, wherein the first depth is less than about 1.5 microns and the second depth is greater than about 2 microns.

15. The method of claim 1, wherein a distance between the first depth and the second depth is greater than about 1 micron.

16. The method of claim 1, wherein the first implant dose and the second implant dose are each less than about 1E13/cm².

17. The method of claim 1, wherein the first implant energy is greater than the second implant energy.

18. A silicon carbide semiconductor layer comprising:
a buried implanted region that is buried in the silicon carbide layer at a first depth from a surface of the silicon carbide layer, the buried implanted region defined by an implant doping profile having a first thickness between the first depth and a second depth, wherein the second depth is greater than the first depth;
wherein the buried implanted region has a variation in doping concentration between the de-channeled peak and the channeled peak of less than about 15%.

19. The silicon carbide semiconductor layer of claim 18, wherein the first depth corresponds to a de-channeled implant peak of an implant operation used to form the buried implanted region and a channeled implant peak of the implant operation used to form the buried implanted region.

20. The silicon carbide semiconductor layer of claim 18, wherein the combined doping profile has a variation in doping concentration between the de-channeled peak and the channeled peak between about 5% and about 10%.

21. The silicon carbide semiconductor layer of claim 18, wherein the combined doping profile has a variation in doping concentration between the de-channeled peak and the channeled peak of about 5%.

22. The silicon carbide semiconductor layer of claim 18, wherein the buried implanted region comprises a channel region of a vertical semiconductor device.

23. The silicon carbide semiconductor layer of claim 22, wherein the vertical semiconductor device comprises a vertical junction field effect transistor device.

24. The silicon carbide semiconductor layer of claim 18, wherein the buried implanted region comprises a current spreading layer of a semiconductor device.

25. The silicon carbide semiconductor layer of claim 18, wherein the buried implanted region has a dopant concentration tail beneath the buried implanted region that decreases at a rate of greater than about 1.0E17 atoms/(cm³-micron).

26. The silicon carbide semiconductor layer of claim 25, wherein the dopant concentration tail decreases at a rate of greater than about 1.2E17 atoms/(cm³-micron).

27. The silicon carbide semiconductor layer of claim 25, wherein the dopant concentration tail decreases at a rate of greater than about 1.0E17 atoms/(cm³-micron) and less than 1.5E17 atoms/(cm³-micron).

28. The silicon carbide semiconductor layer of claim 18, wherein the first depth is less than about 1.5 microns and the second depth is greater than about 2 microns.

29. The silicon carbide semiconductor layer of claim 18, wherein a distance between the first depth and the second depth is greater than about 1 micron.

30. A silicon carbide semiconductor layer comprising:
a buried implanted region that is buried in the silicon carbide layer at a first depth from a surface of the silicon carbide layer, the buried implanted region defined by an implant doping profile having a first thickness between the first depth and a second depth, wherein the second depth is greater than the first depth;
wherein the buried implanted region has a dopant concentration tail beneath the buried implanted region that decreases at a rate of greater than about 1.0E17 atoms/(cm³-micron).

31. The silicon carbide semiconductor layer of claim 30, wherein the dopant concentration tail decreases at a rate of greater than about 1.2E17 atoms/(cm³-micron).

32. The silicon carbide semiconductor layer of claim 30, wherein the dopant concentration tail decreases at a rate of greater than about 1.0E17 atoms/(cm³-micron) and less than 1.5E17 atoms/(cm³-micron)

33. The silicon carbide semiconductor layer of claim 30, wherein the buried implanted region has a variation in doping concentration between the de-channeled peak and the channeled peak of less than about 15%.

34. The silicon carbide semiconductor layer of claim 30, wherein the first depth corresponds to a de-channeled implant peak of an implant operation used to form the buried implanted region and a channeled implant peak of the implant operation used to form the buried implanted region.

35. The silicon carbide semiconductor layer of claim 30, wherein the combined doping profile has a variation in doping concentration between the de-channeled peak and the channeled peak between about 5% and about 10%.

36. The silicon carbide semiconductor layer of claim 30, wherein the combined doping profile has a variation in doping concentration between the de-channeled peak and the channeled peak of about 5%.

37. The silicon carbide semiconductor layer of claim 30, wherein the first depth is less than about 1.5 microns and the second depth is greater than about 2 microns.

38. The silicon carbide semiconductor layer of claim 30, wherein a distance between the first depth and the second depth is greater than about 1 micron.
